(19) United States
(12) Patent Application Publication
(10) Pub. No.: US 2005/0186748 A1
(43) Pub. Date: Aug. 25, 2005

(54) Method of manufacturing semiconductor device

(75) Inventors: Ryoji Hasumi, Yokohama-shi (JP); Katsura Miyashita, New York, NY (US)

Correspondence Address: FOLEY AND LARDNER;SUITE 500, 3000 K STREET NW, WASHINGTON, DC, 20007, US

(73) Assignee: KABUSHIKI KAISHA TOSHIBA

(21) Appl. No.: 11/038,475

(22) Filed: Jan. 21, 2005

(30) Foreign Application Priority Data
Jan. 22, 2004 (JP) 2004-013992

(51) Int. Cl. H01L 21/336; H01L 21/425

(52) U.S. Cl. 438/305; 438/527; 438/306

(57) ABSTRACT

A method of manufacturing a semiconductor device including a plurality of MIS transistors formed on a semiconductor substrate, includes forming a plurality of gate electrodes associated with the MIS transistors on the semiconductor substrate, with a plurality of gate insulating films interposed between the gate electrodes and the semiconductor substrate, respectively, and successively forming a plurality of impurity diffusion regions for LDD regions in the semiconductor substrate, at decreasing junction depths, respectively, by using lithography and ion implantation, such that each of the impurity diffusion regions being provided on both sides of a respective one of the gate electrodes.

### CROSS-REFERENCE TO RELATED APPLICATIONS

This application is based upon and claims the benefit of priority from prior Japanese Patent Application No. 2004-013992, filed Jan. 22, 2004, the entire contents of which are incorporated herein by reference.

### BACKGROUND OF THE INVENTION

1. Field of the Invention

The present invention relates to a method of manufacturing a semiconductor device, and in particular a semiconductor device provided with a metal oxide semiconductor (MOS) having a lightly doped drain (LDD) structure.

2. Description of the Related Art

In recent years, semiconductor integrated circuits have been formed at a higher density, and have also been made smaller. Under such circumstances, semiconductor integrated circuits employ an LDD structure as the structures of MOS transistors to restrict the short channel effect of the MOS transistors, and improve the driving function of the MOS transistors.

In the LDD structure, regions whose impurity concentration is low are provided as LDD regions in end portions of source and drain regions, which are located adjacent to the channel. In general, LDD regions are formed before forming insulating films on the side walls of gate electrodes, by doping impurities, with the gate electrodes used as masks, such that the concentration of the impurities in the LDD regions is low.

It should be noted that there is a case where when a number of MOS transistors, which are different in junction depth of LDD regions (i.e., a depth from the surface of the semiconductor substrate to the PN junction), are formed on the same semiconductor substrate. This is because there is a case where a plurality of power supply voltages are handled in a semiconductor integrated circuit, or where the MOS transistors are required to have different levels of reliability.

In such a manner, in the case where a number of MOS transistors are formed on the semiconductor substrate such that the junction depths of their LDD regions are different, each time the LDD regions of each of the MOS transistors are formed, the following steps are carried out: a resist film is formed on the semiconductor substrate, and is patterned to expose a region where each MOS transistor will be formed to have a predetermined depth; impurities are doped; and then the resist film is removed.

The above step of removing the resist film is carried out by, e.g., performing ashing and cleaning using an alkaline liquid. At the time of ashing, the surface of the semiconductor substrate is oxidized, and a SiO₂ film is formed on the surface of the semiconductor substrate. At this time, impurities in the LDD regions are taken into the SiO₂ film. In this state, when cleaning is carried out with the alkaline liquid, the SiO₂ film is etched. Thereby, impurities taken in the SiO₂ film is eliminated therefrom, thus reducing the amount of the impurities in the LDD regions.

In LDD regions having a relatively large junction depth, even when impurities are eliminated from the LDD regions in the resist removing step, the amount of the eliminated impurities is negligible with respect to the amount of impurities doped in the LDD regions. It is therefore unnecessary to consider the number of times the resist removing step should be carried out after doping of impurities. Thus, in the case of forming LDD regions the junction depths of which are all relatively large, it is possible to repeat ion implantation for formation of LLD regions having the second smallest junction depth, after ion implantation for formation of LDD regions having the smallest junction depth.

However, for example, in the case of forming LDD regions having a junction depth of 30 nm or less, the position of doped impurities is close to the surface of the substrate. Thus, when ion implantation is repeated to form LDD regions having a large junction depth, after ion implantation for formation of LDD regions having a small junction depth, the amount of the impurities doped in the semiconductor substrate is decreased as the number of times the resist removing step is carried out increases.

Then, when impurities are eliminated from LDD regions having a small junction depth, the resistance value of the LDD regions is increased. As a result, the driving function of a MOS transistor having the LDD regions is lowered. This problem is more serious when the concentration of the impurities doped in the LDD regions is low.

This kind of relevant technique is disclosed in the following document: Ultrashallow Junction Formation for Sub-100 nm Complementary Metal-Oxide-Semiconductor Field-Effect Transistor by Controlling Enhanced Diffusion, K. Ohuchi et al., Jpn. J. Appl. Phys. Vol. 40(2001), pp. 2701-2705, April 2001.

### BRIEF SUMMARY OF THE INVENTION

A method of manufacturing a semiconductor device including a plurality of MIS (metal insulator semiconductor) transistors formed on a semiconductor substrate, according to the first aspect of the present invention, comprises: forming a plurality of gate electrodes associated with the MIS transistors on the semiconductor substrate, with a plurality of gate insulating films interposed between the gate electrodes and the semiconductor substrate, respectively; and successively forming a plurality of impurity diffusion regions for lightly doped drain (LDD) regions in the semiconductor substrate, at decreasing junction depths, respectively, by using lithography and ion implantation, such that each of the impurity diffusion regions being provided on both sides of a respective one of the gate electrodes.

A method of manufacturing a semiconductor device including a plurality of MIS transistors formed on a semiconductor substrate, according to the second aspect of the present invention, comprises: forming a plurality of gate electrodes associated with the MIS transistors on the semiconductor substrate, with a plurality of gate insulating films interposed between the gate electrodes and the semiconductor substrate, respectively; and successively forming a plurality of impurity diffusion regions for LDD regions in the semiconductor substrate, in descending order of depth at which an impurity concentration is peak, by using lithography and ion implantation, such that each of the impurity diffusion regions being provided on both sides of a respective one of the gate electrodes.

### BRIEF DESCRIPTION OF THE SEVERAL VIEWS OF THE DRAWING

FIG. 1 is a cross-sectional view of a semiconductor device according to the first embodiment of the present invention.

FIG. 2 is a cross-sectional view for use in explaining an example of a method of manufacturing the semiconductor device shown in FIG. 1.

FIG. 3 is a cross-sectional view showing the manufacturing method subsequently to FIG. 2.

FIG. 4 is a cross-sectional view showing the manufacturing method subsequently to FIG. 3.

FIG. 5 is a cross-sectional view showing low-concentration impurity regions 10 and a through oxide film 13 shown in FIG. 4.

FIG. 6 is a cross-sectional view showing the manufacturing method subsequently to FIG. 5.

FIG. 7 is a cross-sectional view showing the manufacturing method subsequently to FIG. 6.

FIG. 8 is a cross-sectional view showing the manufacturing method subsequently to FIG. 7.

FIG. 9 is a cross-sectional view showing a low-concentration impurity region 40 and a through oxide film 43 in FIG. 8.

FIG. 10 is a cross-sectional view showing the manufacturing method subsequently to FIG. 9.

FIG. 11 is a cross-sectional view showing the manufacturing method subsequently to FIG. 10.

FIG. 12 is a cross-sectional view showing the manufacturing method subsequently to FIG. 11.

FIG. 13 is a cross-sectional view of a semiconductor device according to the second embodiment of the present invention.

FIG. 14 is a cross-sectional view showing depths at which the impurity concentrations of the low-concentration impurity regions 50 and low-concentration impurity regions 60 shown in FIG. 13 are peak, respectively.

FIG. 15 is a cross-sectional view showing an example of a method of manufacturing the semiconductor device shown in FIG. 13.

FIG. 16 is a cross-sectional view showing the manufacturing method subsequently to FIG. 15.

FIG. 17 is a cross-sectional view showing the manufacturing method subsequently to FIG. 16.

FIG. 18 is a cross-sectional view showing the manufacturing method subsequently to FIG. 17.

FIG. 19 is a cross-sectional view showing the manufacturing method subsequently to FIG. 18.

FIG. 20 is a cross-sectional view showing the manufacturing method subsequently to FIG. 19.

FIG. 21 is a cross-sectional view showing the manufacturing method subsequently to FIG. 20.

### DETAILED DESCRIPTION OF THE INVENTION

The embodiments of the present invention will be explained with reference to the accompanying drawings. In the following description, structural elements having the same functions and same structures will be denoted by the same reference numerals, respectively. After they are each explained one time, their explanations will not be repeated, except as need arises.

### First Embodiment

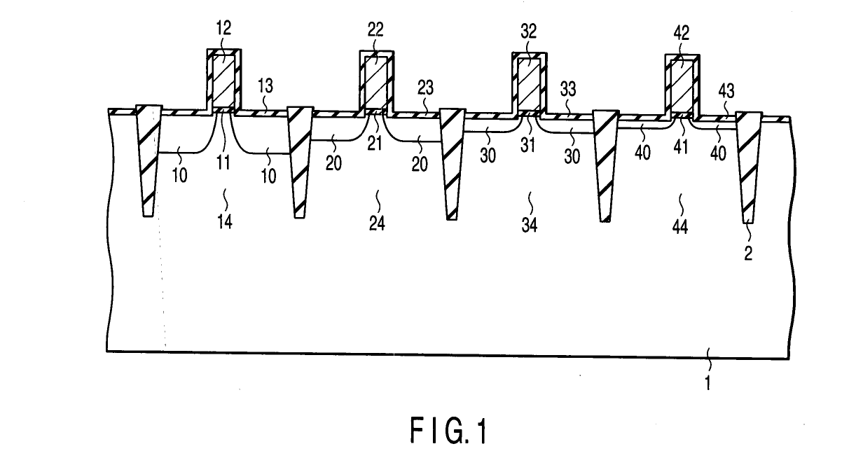

FIG. 1 is a cross-sectional view of a semiconductor device according to the first embodiment of the present invention. To be more specific, FIG. 1 is a cross-sectional view of low-concentration impurity diffusion regions (which will be hereinafter referred to as low-concentration impurity regions) before formations of deep source and drain regions. Part of the low-concentration impurity regions will become LDD region layers.

The LDD regions are impurity diffusion layers having a relatively low concentration, which are formed at end portions of a drain region and a source region of a MOS transistor, which are located adjacent to the channel. When a MOS transistor is formed to include such LDD regions, an electric field concentratedly generated at the end portion of the drain region is reduced, thus restricting a hot carrier effect.

More specifically, when the LDD regions are provided in the above manner, resistor element is connected between the channel and drain terminal, as a result of which an electric field in a depletion layer of the drain terminal can be reduced by a voltage drop at the LDD regions.

The deep source and drain regions are diffusion layers which are formed after formation of the low-concentration impurity regions, and have a higher impurity concentration than the low-concentration impurity regions. The junction between the deep source and drain regions is located in a deeper position than that between the low-concentration impurity regions.

In the first embodiment, low-concentration impurity regions 10, 20, 30 and 40 are formed in the same semiconductor substrate 1 (e.g., a Si substrate). The low-concentration impurity regions 10, 20, 30 and 40 are different in junction depth (which is a depth from the surface of the substrate to the junction boundary of the PN junction). The junction depths of the low-concentration impurity regions 10, 20, 30 and 40 become smaller in this order (10>20>30>40).

At the surface of the semiconductor substrate 1, element isolating regions 2 are formed by, e.g., a shallow trench isolation (STI) method in order to isolate element regions 14, 24, 34 and 44 where MOS transistors are to be formed, respectively. In such a manner, the element regions 14, 24, 34 and 44 are formed to be isolated from each other. The element isolating regions 2 are formed of, e.g., SiO₂.

On the element region 14, a gate electrode 12 is formed, with an gate insulating film 11 interposed therebetween. Similarly, gate electrodes 22, 32 and 42 are formed on the element regions 24, 34 and 44, with gate insulating films 21, 31 and 41 interposed therebetween, respectively. The gate insulating films 11, 21, 31 and 41 are formed of, e.g., SiO₂, and the gate electrodes 12, 22, 32 and 42 are formed of, e.g., polysilicon.

Low-concentration impurity regions 10 are formed in portions of the surface of the semiconductor substrate 1, which are located on the both sides of the gate electrode 12. Furthermore, a through oxide film 13 is formed on the surface of the element region 14 and the top and both side walls of the gate electrode 12. The through oxide film 13 is formed of, for example, SiO₂. Similarly, at the element regions 24, 34 and 44, low-concentration impurity regions 20, 30 and 40 and through oxide films 23, 33 and 43 are provided. In such a manner, a semiconductor device having such a structure as shown in FIG. 1 is obtained.

In the case where the MOS transistors are of a p-type, the semiconductor substrate 1 is of an n-type, and impurities are of a p-type. Furthermore, in the substrate, n-type wells may be formed, and p-type MOS transistors may be formed in the n-type wells.

On the other hand, in the case where the MOS transistors are of an n-type, the semiconductor substrate 1 is of a p-type, and impurities are of an n-type. Furthermore, in the substrate, p-type wells may be formed, and n-type MOS transistors may be formed in the p-type wells.

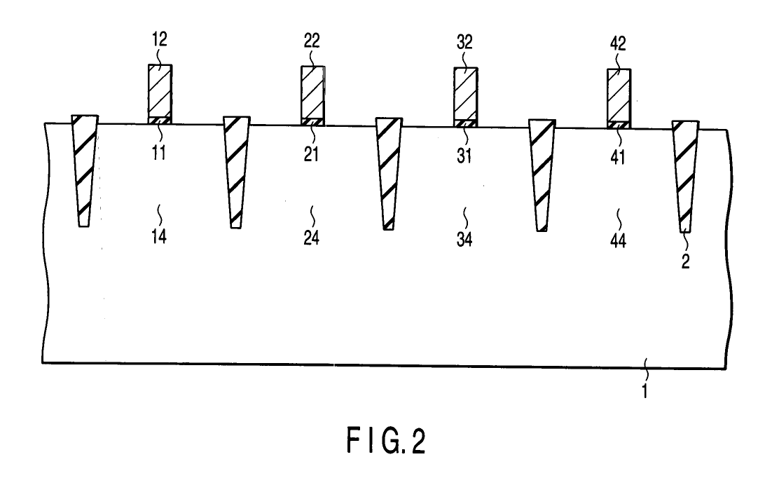

Next, an example of the method of manufacturing the semiconductor device shown in FIG. 1 will be explained with reference to FIGS. 2 to 12.

In a step corresponding to FIG. 2, the element isolating regions 2 are formed in the semiconductor substrate 1 by, e.g., the STI method. Thereby, the element regions 14, 24, 34 and 44 are formed. Next, the gate insulating films 11, 21, 31 and 41 are formed on the element regions 14, 24, 34 and 44, respectively. Then, on the gate insulating films 11, 21, 31 and 41, the gate electrodes 12, 22, 32 and 42 are formed of polysilicon, respectively.

The above gate insulating films and gate electrodes are each patterned by, e.g., a lithography method to have a desired shape. It should be noted that the gate electrodes may be provided as dummy electrodes formed of amorphous silicon or the like. The dummy electrodes can be replaced by metal gate electrodes or the like, e.g., after formation of the diffusion layers.

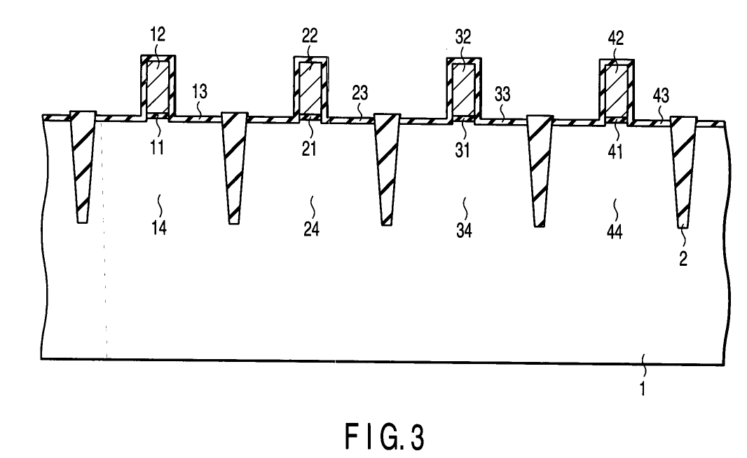

Next, in a step corresponding to FIG. 3, the surface of the semiconductor substrate 1 is oxidized by a thermal oxidizing method, thereby forming the through oxide films 13, 23, 33 and 43. To be more specific, the through oxide films 13, 23, 33 and 43 are formed of SiO₂, and are used to prevent impurities from leaving from the surface of the semiconductor substrate 1 to the outside when the impurities are ion-implanted into the semiconductor substrate 1.

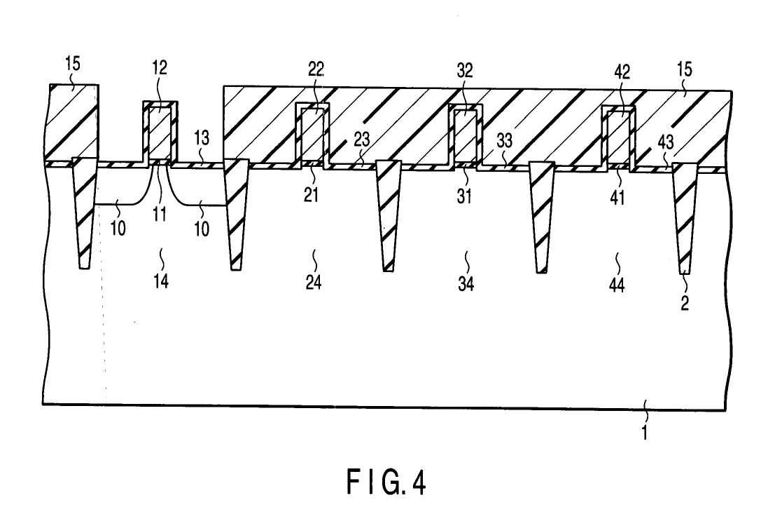

Next, in a step corresponding to FIG. 4, the element region 14 is exposed by the lithography method. To be more specific, first, the surface of the semiconductor substrate 1 is coated with a resist film 15. Then, the resist film 15 is subjected to patterning to expose the element region 14 in which the low-concentration impurity regions 10 whose junction depth is the largest of all the low-concentration impurity regions are to be formed.

Then, impurities are ion-implanted into the element region 14, with the resist film 15 used as a mask. In this case, in the case of forming n-type MOS transistors, the impurities are of an n-type as mentioned above, and arsenic (As) is used as the n-type impurities. In contrast, in the case of forming p-type MOS transistors, impurities are of a p-type, and boron (B) is used as the p-type impurities.

The following is an example of the above ion-implanting step:

First, impurities are ionized, and an electric field is then added thereto, thereby moving obtained ions. Then, an injection energy is added to the ions, electrostatically accelerating the ions, and applying the ions to the semiconductor substrate 1 in a scanning manner. Furthermore, the semiconductor substrate 1 is annealed in order to restore a lattice defect which is generated due to ion implantation to a good state, and electrically activate the implanted ions.

The above annealing step may be carried out each time a pair of low-concentration impurity regions are formed, or it may be carried out after formation of all the pairs of low-concentration impurity regions. Alternatively, the annealing step may be carried out after formation of the deep source and drain regions.

The junction depth of low-concentration impurity regions is controlled by the injection energy given to the ions. Also, it can be controlled by the mass of impurity to be ion-implanted.

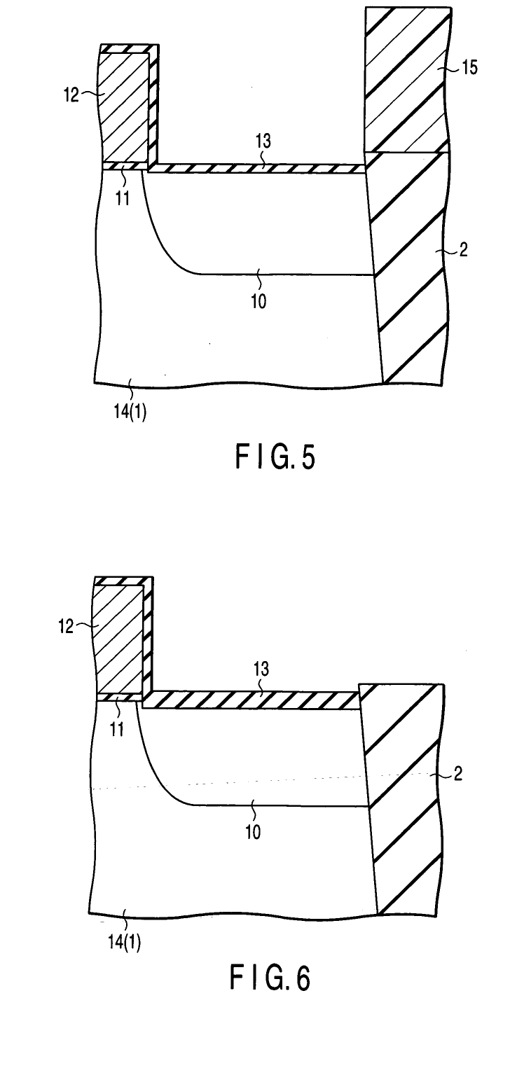

FIG. 5 is a cross-sectional view showing the low-concentration impurity region 10 and through oxide film 13 shown in FIG. 4. In a step corresponding to FIG. 6, the resist film 15 is subjected to ashing (i.e., etching). In this ashing step, for example, oxygen is decomposed with plasma to generate active oxygen atoms or ozone, and the oxygen atoms or ozone are transferred to the semiconductor substrate 1 to etch the resist film 15.

Due to the ashing step, the thickness of the through oxide film 13 on the low-concentration impurity region 10 is increased to be greater than that before the ashing step is carried out. Thereby, the impurities in the low-concentration impurity region 10 are taken into the through oxide film 13 on the substrate 1.

It should be noted that the through oxide film 13 is not necessarily required to be provided. That is, the above phenomenon occurs even when the through oxide film 13 is not provided. To be more specific, in the ashing step, the surface of the semiconductor substrate 1 is oxidized, thereby forming an oxide film. As a result, impurities in the low-concentration impurity regions 10 are taken into the oxide film on the substrate 1.

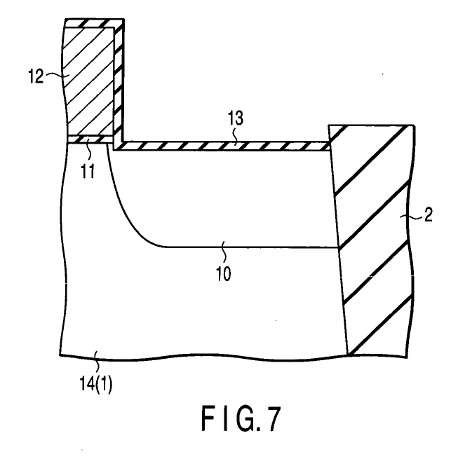

In a step corresponding to FIG. 7, the surface of the semiconductor substrate 1 is wet-cleaned. This wet cleaning is carried out by using, for example, an alkaline liquid (e.g., an NC₂ based liquid). In this cleaning step, part of the through oxide film 13 on the low-concentration impurity regions 10 is etched. As a result, the impurities are eliminated from the oxide film 13. That is, impurities in the low-concentration impurity regions 10 are eliminated therefrom.

It should be noted that in the above ashing step and cleaning step, part of the surface of each of the element regions 24, 34, and 44 is also etched by the same amount as part of the surface of the element region 14. However, in the ashing step and cleaning step, elimination of impurities does not occur in the element regions 24, 34 and 44, since impurities are not ion-implanted thereinto in the processing for forming the low-concentration impurity regions 10.

Next, the low-concentration impurity regions 20 are formed, and their junction depth is the second largest of the junction depths of all the pairs of low-concentration impurity regions. The processing for forming the low-concentration impurity regions 20 is carried out in the same manner as that for forming the low-concentration impurity regions 10, and its explanation will thus be omitted. Also, no figure showing the processing for forming the low-concentration impurity regions 20 is provided.

In an ashing step and a cleaning step using an alkaline liquid in the processing for forming the low-concentration impurity regions 20, part of the surface of each of the element regions 14, 24, 34 and 44 is etched. Thereby, impurities are eliminated from the low-concentration impurity regions 10 and 20. Elimination of impurities does not occur in the element regions 34 and 44, since impurities are not ion-implanted thereinto in the processing for forming the low-concentration impurity regions 20.

Next, the low-concentration impurity regions 30 are formed, and their junction depth is the third largest. The processing for forming the low-concentration impurity regions 30 is also carried out in the same manner as that for forming the low-concentration impurity region 10, and its explanation will thus be omitted. Also, no figure showing the processing for forming the low-concentration impurity regions 30 is provided.

In an ashing step and a cleaning step using an alkaline liquid in the processing for forming the low-concentration impurity regions 30, part of the surface of the element regions 14, 24, 34 and 44 is etched. Thereby, impurities are eliminated from the low-concentration impurity regions 10, 20 and 30. This does not occur in the element region 44, since impurities are not ion-implanted thereinto in the processing for forming the low-concentration impurity region 30.

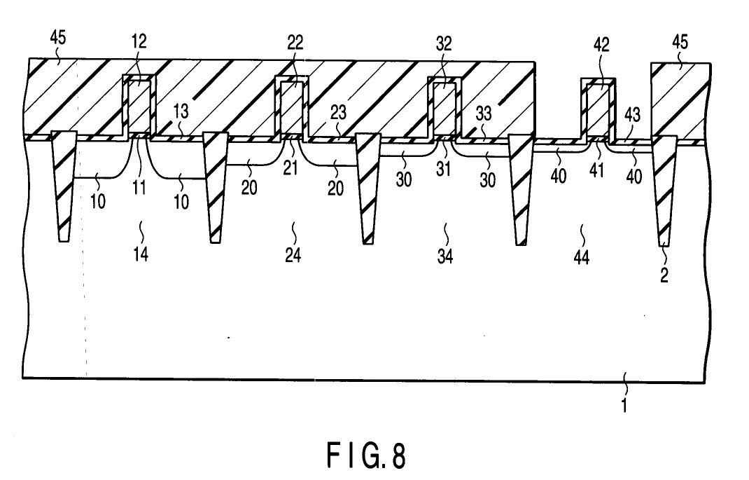

Next, in a step corresponding to FIG. 8, the surface of the semiconductor substrate is coated with a resist film 45. Then, the resist film 45 is subjected to patterning to expose the element region 44 in which the low-concentration impurity regions 40 whose junction depth is the smallest of all the pairs of low-concentration impurity regions are to be formed. Then, impurities are ion-implanted into the element region 44, with the resist film 45 used as a mask.

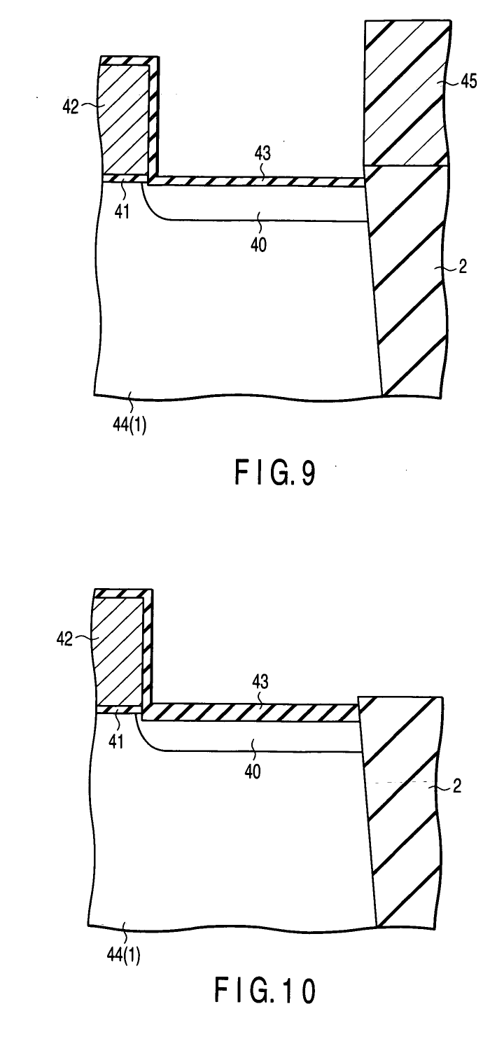

FIG. 9 is a cross-sectional view showing the low-concentration impurity regions 40 and through oxide film 43 shown in FIG. 8. In a step corresponding to FIG. 10, the resist film 45 is subjected to ashing. This ashing step is the same as the ashing step for the resist film 15. Due to the ashing step, the thickness of the through oxide film 43 on the low-concentration impurity regions 40 is increased to be greater than that before the ashing step is carried out. Thereby, impurities in the low-concentration impurity regions 40 are taken into the through oxide film 43.

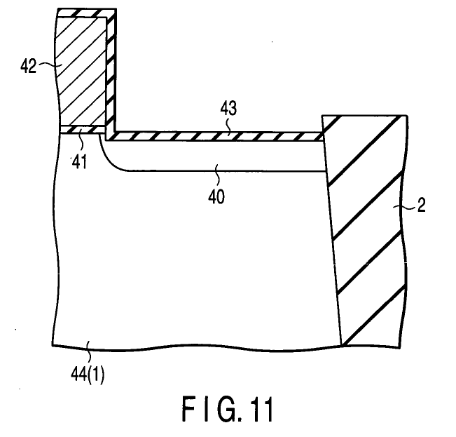

In a step corresponding to FIG. 11, the surface of the semiconductor substrate 1 is cleaned with the alkaline liquid. In this cleaning step, part of the through oxide film 43 on the low-concentration impurity regions 40 is etched. Thereby, impurities are eliminated from the through oxide film 43. That is, impurities are eliminated from the low-concentration impurity regions 40. Also, impurities are eliminated from the low-concentration impurity regions 10, 20 and 30.

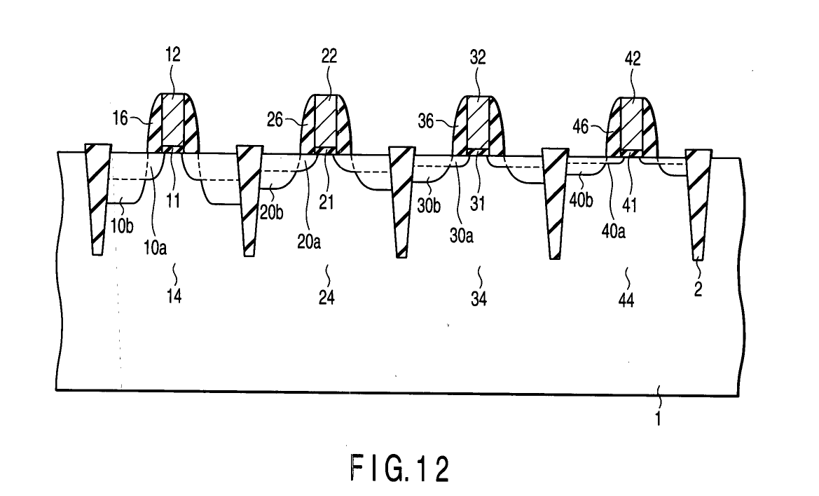

Thereafter, deep source and drain regions are formed. To be more specific, in a step corresponding to FIG. 12, gate side wall insulating films 16, 26, 36 and 46 are formed on side walls of the gate electrodes 12, 22, 32 and 42 such that on the both side walls of each of these gate electrodes, associated two gate side wall insulating films are formed. It should be noted that in FIG. 12, an illustration of the through oxide film is omitted.

High-concentration impurities are ion-implanted into the semiconductor substrate 1, with the gate side wall insulating films 16, 26, 36 and 46 used as masks. As a result, portions of the low-concentration impurity regions 10, 20, 30 and 40, which are masked by the gate side wall insulating films 16, 26, 36 and 46, become LDD regions 10a, 20a, 30a and 40a, respectively.

Furthermore, portions of the low-concentration impurity regions 10, 20, 30 and 40, into which the high-concentration impurities are ion-implanted, become deep source and drain regions 10b, 20b, 30b and 40b, respectively, whose junction depths are larger than the LDD regions.

In a semiconductor device manufactured in the above manner, the number of times the step of removing the resist film after formation of the low-concentration impurity regions 40 whose junction depth is the smallest is carried out can be decreased to one. Accordingly, the amount of impurities eliminated from the low-concentration impurity regions 40 can be minimized, thus restricting an increase in the resistance value of the low-concentration impurity regions 40.

Furthermore, the above feature of the first embodiment is more advantageous as the junction depth of the LDD region deceases. It is found from the result of an experiment conducted by the inventors of the present invention that the above feature is more advantageous in the case of forming a MOS transistor including LDD regions the junction depth of which is 30 nm or less.

In the above resist removing step, the position of the surface of the semiconductor substrate 1 is lowered. This is because in the ashing step and cleaning step in the resist removing step, the surface of the semiconductor substrate 1 on the low-concentration impurity regions is etched (to be more specific, part of the oxidized semiconductor substrate 1 is etched).

In the low-concentration impurity regions 10 whose junction depth is the largest, the resist removing step is carried out four times. Accordingly, the position of the semiconductor substrate is further lowered, thus eliminating impurities from the low-concentration impurity regions 10.

However, an increase in the resistance value of the low-concentration impurity regions 10 does not greatly effect the characteristics of the semiconductor device, since the junction depth of the low-concentration impurity regions 10 is large. Therefore, lowering of the driving function of a MOS transistor including the low-concentration impurity regions 10 does no matter.

As explained above in detail, in the first embodiment, four pairs of LDD regions having different junction depths are successively formed from a pair of LDD regions whose junction depth is the largest to a pair of LL regions whose junction depth is the smallest.

Therefore, in the first embodiment, lowering of the impurity concentration of the LDD regions whose junction depth is the smallest can be restricted, thus restricting an increase in the resistance value of the LDD regions which is caused by lowering of the impurity concentration. Also, lowering of the driving function of a MOS transistor including the LDD regions can be restricted.

As is clear from the above, the influence of elimination of impurities on the entire semiconductor device can be minimized, since the above pairs of LLD regions are successively formed from a pair of LDD regions whose junction depth is the largest, the influence of elimination of impurities from the LDD regions on the semiconductor device can be minimized.

Also, in the first embodiment, before the ashing step, the through oxide film is formed of a thermal oxide film, thus restricting the variance between the thicknesses of oxide films formed in respective ashing steps which would occur if the through oxide film were not formed, and also the variance between the amounts of impurities eliminated in the respective ashing steps which would occur if the through oxide film were not formed.

To be more specific, if the through oxide film is not provided, an oxide film having a great thickness is formed on the substrate 1 in the first ashing step. Unlike the through oxide film, this oxide film is not formed to have a predetermined thickness, since it is not controllably formed. Therefore, the amount of eliminated impurities varies from one wafer to another. However, this variation can also be restricted due to provision of the through oxide film, since, as stated above, the through oxide film can restrict the variance between the thicknesses of oxide films formed in respective ashing steps.

Furthermore, in the first embodiment, the processing for forming the low-concentration impurity regions adopts ion implantation. Therefore, impurities are doped at a high precision, and the concentration of the impurities can be accurately controlled.

In addition, the step of forming the through oxide film may be omitted. If it is omitted, in the ashing step, SiO₂ films are formed on portions of the surface of the semiconductor substrate 1. That is, impurities in the LDD regions are taken into the SiO₂ films. Thereafter, in the cleaning step, the SiO₂ films are etched. Consequently, impurities in the LDD regions are eliminated therefrom.

However, in the manufacturing method according to the first embodiment, a number of pairs of LDD regions having different junction depths are formed, thus restricting lowering of the concentration of impurities in the LDD regions whose junction depth is small.

### Second Embodiment

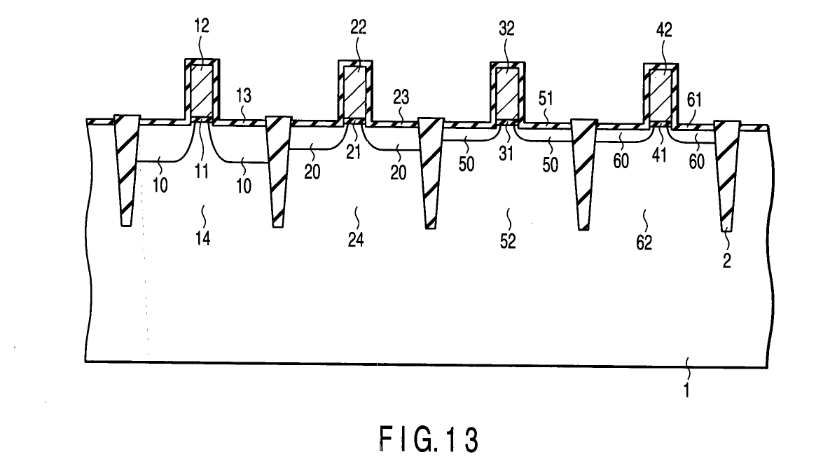

FIG. 13 is a cross-sectional view of a semiconductor device according to the second embodiment of the present invention.

In the second embodiment, low-concentration impurity regions 10, 20, 50 and 60 having different junction depths are formed on the same semiconductor substrate 1. The junction depth of the low-concentration impurity regions 10 is larger than that of the low-concentration impurity regions 20, which is larger than that of the low-concentration impurity regions 50. The junction depth of the low-concentration impurity regions 50 is substantially equal to that of the low-concentration impurity regions 60.

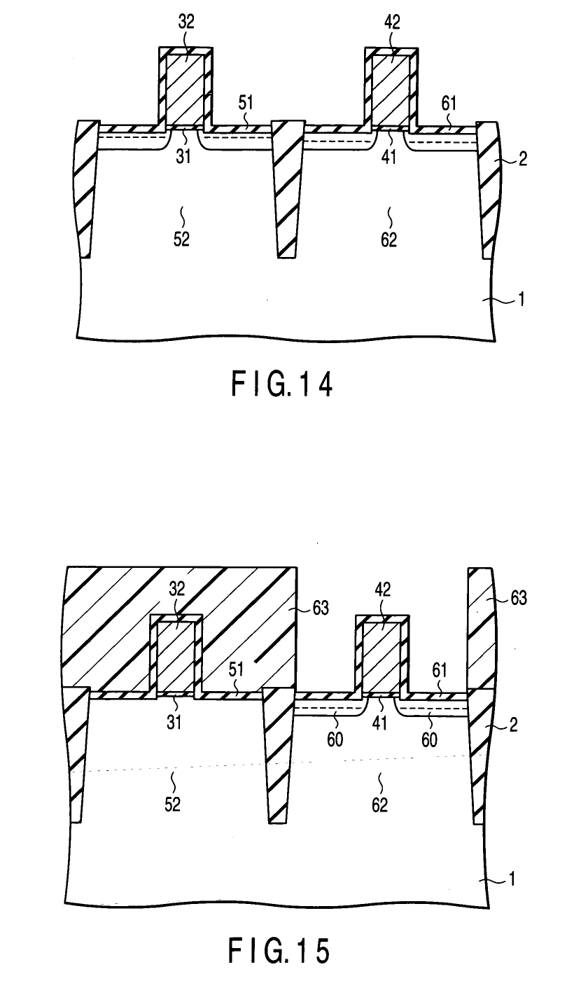

The low-concentration impurity regions 50 are different from the low-concentration impurity regions 60 regarding the depth at which the impurity concentration is peak in the impurity density distribution of the low-concentration impurity regions. FIG. 14 is a cross-sectional view showing depths at which the impurity concentrations of the low-concentration impurity regions 50 and low-concentration impurity regions 60 are peak, respectively.

In FIG. 14, broken lines indicate the depths at which the impurity concentrations are peak. As shown in FIG. 14, the depth at which the impurity concentration of each of the low-concentration impurity regions 50 is peak is smaller than that in the low-concentration impurity regions 60.

On the surface of the semiconductor substrate 1, element regions 52 and 62 are formed. A through oxide film 51 is provided on the surface of the element region 52 and the top and both side walls of the gate electrode 32. Similarly, a through oxide film 61 is provided on the surface of the element region 62 and the top and both side walls of the gate electrode 42.

The low-concentration impurity regions 50 are provided in portions of the surface of the semiconductor substrate 1, which are located on the both sides of the gate electrode 32. Similarly, in the element region 62, the low-concentration impurity regions 60 are provided. In such a manner, the semiconductor device obtains such a structure as shown in FIG. 13.

Next, an example of the method of manufacturing the semiconductor device having the structure shown in FIG. 13 will be explained with reference to FIGS. 15-21.

First, the low-concentration impurity regions 10 whose junction depth is the largest are formed. Then, the low-concentration impurity regions 20 whose junction depth is the second largest are formed. The low-concentration impurity regions 10 and 20 are formed in the same manner as in the first embodiment.

Next, in a step corresponding to FIG. 15, the semiconductor substrate 1 is coated with a resist film 63. The resist film 63 is subjected to patterning in order to expose the element region 62 in which the low-concentration impurity regions 60 are to be formed.

Then, impurities are ion-implanted into the element region 62, with the resist film 63 used as a mask. This ion-implantation step is carried out such that the depth at which the impurity concentration is peak is set to correspond to a position indicated by each of broken lines in FIG. 15. In this case, the ion implantation step is carried out while adjusting the injection energy. Also, the depth at which the impurity concentration is peak can be adjusted by changing the kind or amount of impurities to be ion-implanted.

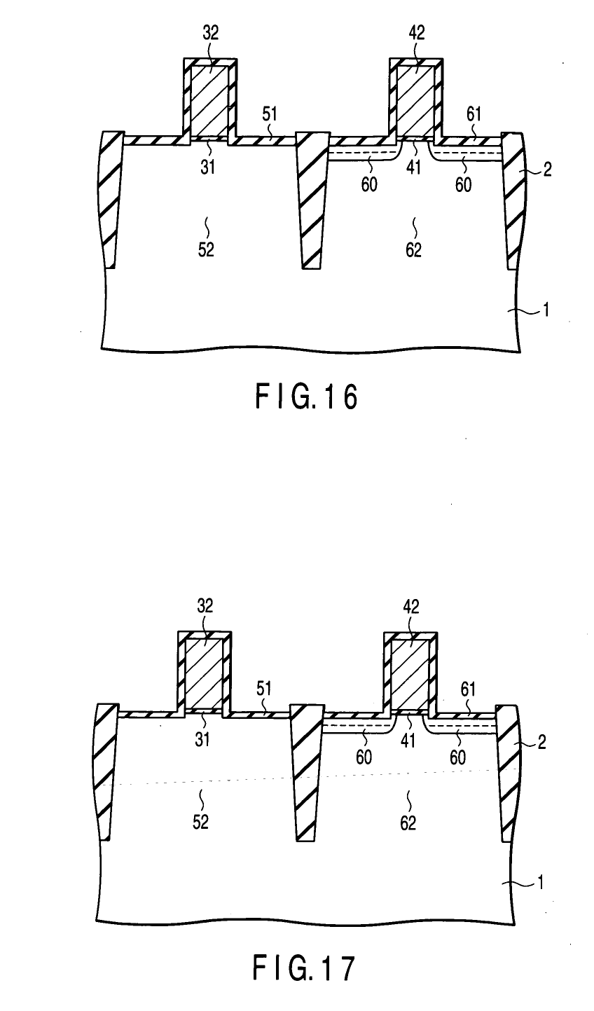

Then, in a step corresponding to FIG. 16, the resist film 63 is subjected to ashing. Due to this ashing step, the thickness of the through oxide film 61 on the low-concentration impurity regions 60 and that of the through oxide film 51 on the element region 52 are increased to be greater than those before the ashing step is carried out. Thereby, impurities in the low-concentration impurity regions 60 are taken into the through oxide film 61. On the other hand, impurities are not taken into the through oxide film 51, since the low-concentration impurity regions 50 are not yet formed.

Then, in a step corresponding to FIG. 17, the surface of the semiconductor substrate 1 is cleaned with an alkaline liquid. In this cleaning step, part of the through oxide film 61 on the low-concentration impurity regions 60 and part of the through oxide film 51 on the element region 52 are etched. As a result, impurities taken into the through oxide film 61 are eliminated therefrom. That is, impurities in the low-concentration impurity regions 60 are eliminated therefrom.

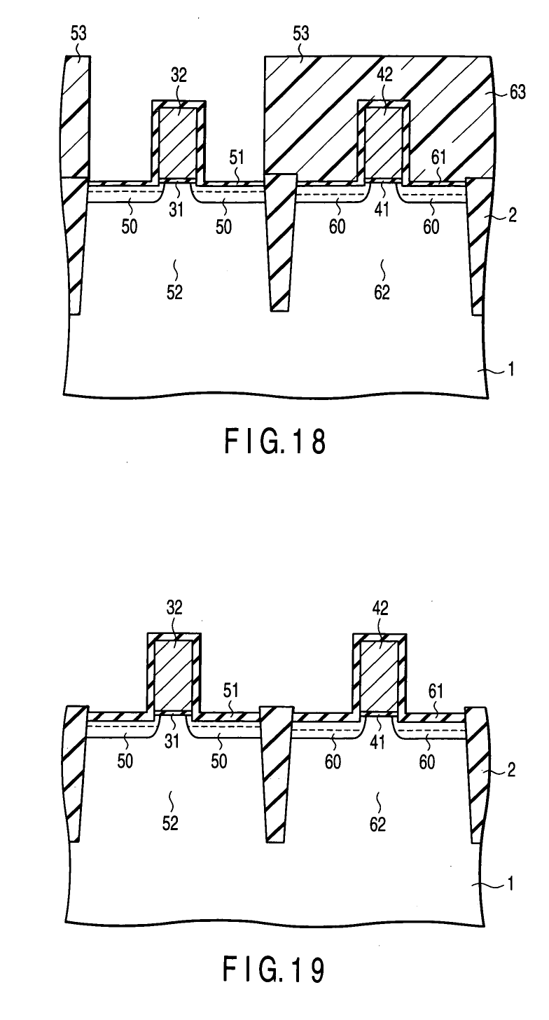

Then, in a step corresponding to FIG. 18, the surface of the semiconductor substrate 1 is coated with a resist film 53. The resist film 53 is subjected to patterning in order to expose the element region 52 in which the low-concentration impurity regions 50 are to be formed.

Then, impurities are ion-implanted into the element region 52, with the resist film 53 used as a mask. This ion implantation step is carried out such that the depth at which the impurity concentration of each of the low-concentration impurity regions 50 is peak is set to correspond to a position indicated by each of broken lines in FIG. 18. That is, the depth at which the impurity concentration of the low-concentration impurity regions 50 is peak is smaller than that in the low-concentration impurity regions 60.

Then, in a step corresponding to FIG. 19, the resist film 53 is subjected to ashing. Due to this ashing step, the thickness of the through oxide film 51 on the low-concentration impurity regions 50 and that of the through oxide film 61 on the low-concentration impurity regions 60 are increased to be greater than those before the ashing step is carried out. Thereby, impurities in the low-concentration impurity regions 50 are taken into the through oxide film 51. Similarly, impurities in the low-concentration impurity regions 60 are taken into the through oxide film 61.

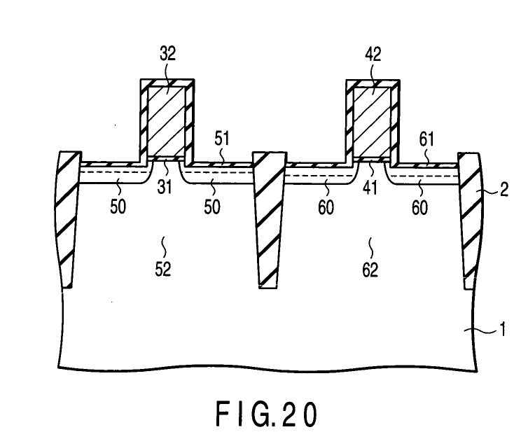

Then, in a step corresponding to FIG. 20, the surface of the semiconductor substrate 1 is cleaned with an alkaline liquid. In this cleaning step, part of the through oxide film 51 on the low-concentration impurity regions 50 and part of the through oxide film 61 on the low-concentration impurity regions 60 are etched. Thereby, impurities taken in the through oxide films 51 and 61 are eliminated therefrom. That is, impurities in the low-concentration impurity regions 50 and 60 are eliminated therefrom.

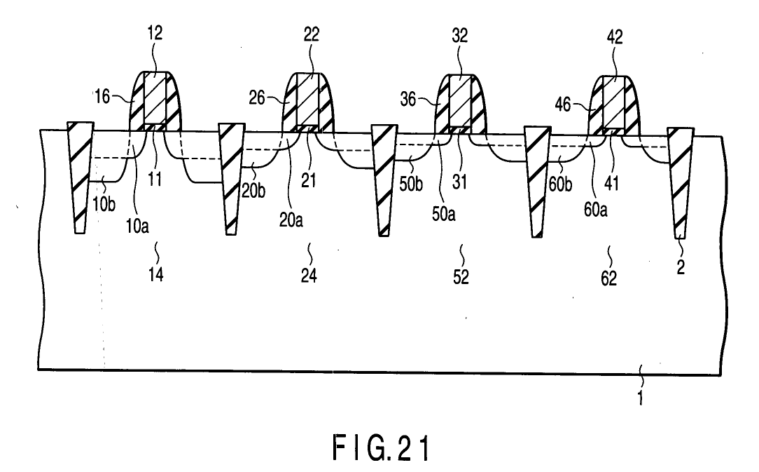

Thereafter, deep source and drain regions are formed. To be more specific, in a step corresponding to FIG. 21, the gate side wall insulating films 16, 26, 36 and 46 are formed on side walls of the gate electrodes 12, 22, 32 and 42 such that on the both side walls of each of these gate electrodes, associated two gate side wall insulating films are formed. It should be noted that in FIG. 21, an illustration of the through oxide film is omitted.

Then, high-concentration impurities are ion-impurities into the semiconductor substrate 1, with the gate side wall insulating films 16, 26, 36 and 46 used as masks. As a result, portions of the low-concentration impurity regions 10, 20, 50 and 60, which are masked by the gate side wall insulating films 16, 26, 36 and 46, become LDD regions 10a, 20a, 50a and 60a, respectively. Furthermore, portions of the low-concentration impurity regions 10, 20, 50 and 60, into which the high-concentration impurities are ion-implanted, become deep source and drain regions 10b, 20b, 50b and 60b, respectively, whose junction depths are larger than the LDD regions.

In a semiconductor device manufactured in the above manner, the number of times the step of removing the resist after formation of the low-concentration impurity regions 50 whose junction depth is the smallest and whose peak impurity concentration depth is the smallest of all the low-concentration impurity regions is carried out can be decreased to one (it should be noted that the above peak impurity concentration depth means the depth at which the impurity concentration is the maximum). Accordingly, the amount of impurities eliminated from the low-concentration impurity regions 50 can be minimized.

In the low-concentration impurity regions 60 whose junction depth is substantially equal to that of the low-concentration impurity regions 50, the above resist removing step is carried out two times. However, the position of the depth at which the impurity concentration of each of the low-concentration impurity regions 60 is peak is deeper than that in the low-concentration impurity regions 50.

Therefore, the amount of impurities eliminated from the low-concentration impurity regions 60 can be made smaller than in the case where the resist removing step is carried out two times on the low-concentration impurity regions 50. Thereby, the amount of impurities eliminated from the entire semiconductor substrate can be restricted.

As explained above in detail, in the second embodiment, the pairs of LDD regions having different junction depths are successively formed at decreasing junction depths from a pair of LDD regions whose junction depth is the largest. Further, if some pairs of LLD regions have substantially the same junction depth, they are formed in descending order of depth in which the impurity concentration is peak (i.e., the peak impurity concentration depth), from a pair of LLD regions whose peak impurity concentration depth is the largest.

Therefore, according to the second embodiment, lowering of the impurity concentrations of LDD regions whose junction depth is small can be restricted, thus restricting an increase in the resistance value of each of the LDD regions, which is caused by lowering of the impurity concentration. In addition, lowering of LDD regions whose depth of peak concentration is small can be restricted.

The above feature of the second embodiment is more advantageous in the case of forming a MOS transistor including LDD regions the junction depth of which is 30 nm or less, as in the first embodiment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method of manufacturing a semiconductor device including a plurality of MIS (metal insulator semiconductor) transistors formed on a semiconductor substrate, comprising:
forming a plurality of gate electrodes associated with the MIS transistors on the semiconductor substrate, with a plurality of gate insulating films interposed between the gate electrodes and the semiconductor substrate, respectively; and
successively forming a plurality of impurity diffusion regions for lightly doped drain (LDD) regions in the semiconductor substrate, at decreasing junction depths, respectively, by using lithography and ion implantation, such that each of the impurity diffusion regions being provided on both sides of a respective one of the gate electrodes.

2. The method according to claim 1, wherein the MIS transistors include a first MIS transistor and a second MIS transistor which contains impurity diffusion regions whose junction depth is smaller than that of the first MIS transistor, and the forming the impurity diffusion regions includes:
forming a first resist film on the semiconductor substrate, the first resist film having an opening which exposes a first region in which the first MIS transistor is to be formed;
ion-implanting impurities into the semiconductor substrate by using the first resist film as a mask;
removing the first resist film;
forming a second resist film on the semiconductor substrate, the second resist film having an opening which exposes a second region in which the second MIS transistors is to be formed;
ion-implanting impurities into the semiconductor substrate by using the second resist film as a mask; and
removing the second resist film.

3. The method according to claim 1, wherein in the forming the impurity diffusion regions, impurity diffusion regions of ones of the MIS transistors, which are substantially the same as each other in junction depth, are formed in descending order of depth at which an impurity concentration is peak.

4. The method according to claim 1, which further comprises, after the forming the gate electrodes, forming insulating films on the semiconductor substrate.

5. The method according to claim 1, which further comprises, after the forming the impurity diffusion regions:
forming gate side wall insulating films such that each of the gate side wall insulating films is provided on both side surfaces of a respective one of the gate electrodes; and
forming a plurality of source and drain regions in the semiconductor substrate by using the gate side wall insulating films as masks, the source and drain regions having junction depths which are larger than those of the impurity diffusion regions.

6. The method according to claim 2, wherein the removing the first resist film includes subjecting the first resist film to ashing, and wet-cleaning a surface of the semiconductor substrate, and the removing the second resist film includes subjecting the second resist film to ashing, and wet-cleaning the surface of the semiconductor substrate.

7. The method according to claim 6, wherein in the subjecting the first resist film to the ashing and the subjecting the second resist film to the ashing, oxygen is used.

8. The method according to claim 6, wherein in the wet-cleaning the surface of the semiconductor substrate, an alkaline liquid is used.

9. The method according to claim 1, which further comprises, after the forming the impurity diffusion regions, annealing the semiconductor substrate to diffuse the impurities.

10. The method according to claim 1, wherein the impurities are of a first conductive type, and the semiconductor substrate is of a second conductive type.

11. A method of manufacturing a semiconductor device including a plurality of MIS transistors formed on a semiconductor substrate, comprising:
forming a plurality of gate electrodes associated with the MIS transistors on the semiconductor substrate, with a plurality of gate insulating films interposed between the gate electrodes and the semiconductor substrate, respectively; and
successively forming a plurality of impurity diffusion regions for LDD regions in the semiconductor substrate, in descending order of depth at which an impurity concentration is peak, by using lithography and ion implantation, such that each of the impurity diffusion regions being provided on both sides of a respective one of the gate electrodes.

12. The method according to claim 11, wherein the MIS transistors include a first MIS transistor and a second MIS transistor which is smaller than the first MIS transistor in the depth at which the impurity concentration is peak, and the forming the impurity diffusion regions includes:
forming a first resist film on the semiconductor substrate, the first resist film having an opening which exposes a first region in which the first MIS transistor is to formed;
ion-implanting impurities into the semiconductor substrate by using the first resist film as a mask;
removing the first resist film;
forming a second resist film on the semiconductor substrate, the second resist film having an opening which exposes a second region in which the second MIS transistor is to be formed;
ion-implanting impurities into the semiconductor substrate by using the second resist film as a mask; and
removing the second resist film.

13. The method according to claim 11, which further comprises, after the forming the gate electrodes, forming insulating films on the semiconductor substrate.

14. The method according to claim 11, which further comprises, after the forming the impurity diffusion regions:
forming gate side wall insulating films such that each of the gate side wall insulating films is provided on both sides of a respective one of the gate electrodes; and
forming a plurality of source and drain regions in the semiconductor substrate by using the gate side wall insulating films as masks, the source and drain regions having junction depths which are larger than those of the impurity diffusion regions.

15. The method according to claim 12, wherein the removing the first resist film includes subjecting the first resist film to ashing, and wet-cleaning a surface of the semiconductor substrate, and the removing the second resist film includes subjecting the second resist film to ashing, and wet-cleaning the surface of the semiconductor substrate.

16. The method according to claim 15, wherein in the subjecting the first resist film to the ashing and the subjecting the second resist film to the ashing, oxygen is used.

17. The method according to claim 15, wherein in the wet-cleaning the surface of the semiconductor substrate, an alkaline liquid is used.

18. The method according to claim 11, which further comprises, after the forming the impurity diffusion regions, annealing the semiconductor substrate to diffuse the impurities.

19. The method according to claim 11, wherein the impurities are of a first conductive type, and the semiconductor substrate is of a second conductive type.
